(19) United States
(12) Patent Application Publication
(10) Pub. No.: US 2016/0223904 A1
(43) Pub. Date: Aug. 4, 2016

(54) REAGENT FOR ENHANCING GENERATION OF CHEMICAL SPECIES

(71) Applicant: TOYO GOSEI CO., LTD., Ichikawa-shi, Chiba (JP)

(72) Inventor: Satoshi Enomoto, Inzai-shi, Chiba (JP)

(21) Appl. No.: 15/026,745

(22) PCT Filed: Oct. 2, 2014
(86) PCT No.: PCT/JP2014/005039

§ 371 Date: Apr. 1, 2016

Related U.S. Application Data
(60) Provisional application No. 61/960,984, filed on Oct. 2, 2013.

(51) Int. Cl. G03F 7/004; G03F 7/20

(52) U.S. Cl. CPC G03F 7/0045; G03F 7/2059

(57) ABSTRACT

A reagent that enhances acid generation of a photoacid generator and composition containing such reagent is disclosed.

### CROSS-REFERENCE TO RELATED APPLICATIONS

This application is a national phase entry under 35 U.S.C. §371 of International Patent Application PCT/JP2014/005039, filed Oct. 2, 2014, designating the United States of America and published in English as International Patent Publication WO 2015/049871 A1 on Apr. 9, 2015, which claims the benefit under 35 U.S.C. section 119(e) and Article 8 of the Patent Cooperation Treaty to U.S. Provisional Patent Application Ser. No. 61/960,984, filed Oct. 2, 2013, the disclosure of each of which is hereby incorporated herein in its entirety by this reference.

### TECHNICAL FIELD

Several aspects of the application relate to the field of chemistry generally and, more specifically, to a composition that enhances generation of chemical species, such as an acid and/or base, even if an inefficient phenomenon is utilized for the generation.

### BACKGROUND

Current high-resolution lithographic processes are based on chemically amplified resists (CARS) and are used to pattern features with dimensions less than 100 nm.

A method for forming pattern features with dimensions less than 100 nm is disclosed in U.S. Pat. No. 7,851,252 (filed on Feb. 17, 2009), the disclosure of which is hereby incorporated herein in its entirety by this reference.

### BRIEF SUMMARY

A first reagent related to an aspect of this disclosure is to generate a first chemical species, at least one of a donation of an electron from such first chemical species and an acceptance of an electron by such first chemical species. Such first chemical species is to be converted to a first product by the at least one of the donation of the electron from the first chemical species and the acceptance of the electron by such first chemical species. Such donation of the electron and the acceptance of the electron of the first chemical species may occur by an excitation of the first chemical species.

The excitation of the first chemical species enhances such donation of the electron and the acceptance of the electron. Such first reagent may have at least one pi-electron system, while such first product may have at least one pi-electron system.

It is preferred that a first excitation energy, which is the lowest excitation energy to excite such first reagent, is greater than a second excitation energy, which is the lowest excitation energy to excite the first product.

It is preferred that such first reagent has a first group that is an aromatic group, while the first product has the first group and a second group that has a pi-electron. It is preferred that, in such first product, the first group interacts electronically with the second group. It is preferred that such first chemical species is to be formed by having a hydrogen atom of the first reagent abstracted.

It is preferred that such first chemical species is to be formed by reacting with a third chemical species formed by supplying an energy to a film formed from a composition containing the first reagent.

It is preferred that the energy is to be supplied to the film by exposing the film to at least one of an extreme ultraviolet light and an electron beam.

A second reagent related to an aspect of this disclosure is to generate a second product.

It is preferred that at least one of a donation of an electron from the second product and an acceptance of an electron by the second product is capable of occurring by an excitation of the second product. Such second product can act as a photosensitizer.

It is preferred that the lowest singlet excited state of the second product is pi-pi* nature since an excited state with pi-pi* nature usually has a relatively longer lifetime than n-pi* nature. A product of the lowest singlet excited state has n-pi*or sigma-pi* excited state, which can be used as a photosensitizer as necessary.

It is preferred that such second reagent and the second product have at least two pi-electron systems. An electronic interaction between the at least two pi-electron systems in such second reagent may be weaker than an electronic interaction between the at least two pi-electron systems in such second product. This will enable such second product to be excited by lower excitation energy compared to such second reagent.

It is preferred that a third excitation energy, which is the lowest excitation energy to excite the second reagent, is greater than a fourth excitation energy, which is the lowest excitation energy to excite the second product.

It is preferred that the second reagent has a third group that is an aromatic group and a fourth group that is an aromatic group, while the second product has the third group, the fourth group and a fifth group.

It is preferred that an electronic interaction between the third group and the fourth group in the second reagent is weaker than an electronic interaction between the third group and the fourth group in the second product.

It is preferred that the electronic interaction between the third group and the fourth group in the second product is an electronic interaction through the fifth group.

It is preferred that the fifth group has a pi-electron system such as carbon-carbon multiple bond and carbon-hetero atom multiple bond. Typical hetero atoms are oxygen, nitrogen and sulfur.

A composition related to an aspect of this disclosure includes any one of such second reagents mentioned above and a precursor, which is to form a second chemical species.

It is preferred that such composition further includes any one of the first reagents mentioned above. It is preferred that such composition further includes a compound that is to react with the second chemical species. It is preferred that such compound has a dissociable group that is to react with the second chemical species.

It is preferred that such composition is capable of being used as a photoresist that is used for manufacturing a device including a first step and a second step. The first step includes an exposure of the photoresist, or a film formed from the photoresist, to at least one of an electron beam and a first light, the wavelength of which is a first wavelength. The second step includes an exposure of the photoresist or a film formed from the photoresist to a second light, the wavelength of which is a second wavelength. It is preferred that the first wavelength is shorter than the second wavelength. It is preferred that the first wavelength is a wavelength shorter than 50 nm.

A method for fabricating a device related to an aspect of this disclosure includes: placing such composition on a member, such that a film including the composition is disposed on the member; and generating the first product in the film by an exposure of the film to at least one of an electron beam and a first light, the wavelength of which is a first wavelength. It is preferred that the first wavelength is shorter than 50 nm.

Such method may further include exposure of the film to a second light, the wavelength of which may be a second wavelength. The second wavelength may be longer than 250 nm. A method fabricating a device related to an aspect of this disclosure includes: placing any one of the compositions mentioned above on a member, such that a film including such composition is disposed on the member; first, exposing the film to at least one of an electron beam and a first light, the wavelength of which is a first wavelength, such that a first portion of the film is exposed to the at least one of the electron beam and the first light, while a second portion of the coating film is not exposed to the at least one of the electron beam and the first light; and, second, exposing the film to a second light, the wavelength of which is a second wavelength. The first wavelength may be shorter than 50 nm. Such method may further include removing the first portion.

Provided is a reagent that enhances acid generation of a photoacid generator (PAG) and composition containing such reagent.

In one aspect of this disclosure, a reagent generates a product through reaction with a chemical species, acceptance of an electron from a substance or donation of an electron to a substance.

Such product can act as a catalyst or enhancer to stimulate a reaction of a precursor by receiving energy such as an electromagnetic ray, a particle ray or heat. A latent image is formed through the process to the formation of such product.

Since such product can be formed by providing such a composition with energy (such as by electromagnetic ray, particle ray, and/or heat), supply of energy to the composition can be utilized as a trigger for formation of the latent image.

The composition is especially useful for a series of chemical processes, even if an inefficient phenomenon, such as photoreaction induced by excitation by a light with low intensity is utilized for the series of chemical processes, since such product formed in the composition can act as a catalyst or enhancer that enhances a desired reaction utilized for the chemical processes.

It is preferred that an intermediate generated from such reagent have a hydrogen atom that can be easily abstracted. Typically, such reagent has hydrogen on an sp3 carbon atom directly connected to an atom of a non-carbon element, such as silicon, germanium, stannum, boron, oxygen, phosphorus, arsenicum, sp2 carbon atom, or sp carbon atom. A typical example of such reagent is an alcohol or carbonyl compound having at least one aryl group connected to a carbon atom bonded to the hydroxyl group, and a hydrogen atom connected to the carbon atom or its derivative having a protecting group for the hydroxyl group or carbonyl group.

Another reagent related to an aspect of this disclosure is at least two aryl groups, or its derivative, having a protecting group for a hydroxyl group or carbonyl group.

Other examples of any one of such reagents mentioned above are compounds having hydrogen on an sp3 carbon atom connected to an atom of a non-carbon element, such as silicon, germanium, stannum, boron, oxygen, phosphorus, or arsenicum through one carbon atom.

Other examples of any one of such reagents mentioned above are compounds having hydrogen on an atom of a non-carbon element, such as silicon, germanium, stannum, boron, oxygen, phosphorus, arsenicum, and sulfur.

Typically, an intermediate (of which a typical example is a ketyl radical) is generated from any one of such reagents mentioned above by having its hydrogen atom abstracted by a reactive species, such as an aryl radical or alkyl radical, generated in the composition by supply of energy to the composition or a film formed of any one of the compositions.

Typically, it is preferred that such intermediate has a reducing ability for reducing a precursor. Such intermediate generated from such reagent mentioned above may have an elimination group or atom that can be removed in conjunction with reduction of the precursor.

Typically, the precursor generates a chemical species such as acid or base by receiving an electron from such intermediate generated from such reagent mentioned above. A reaction of the chemical species such as acid or base with a compound occurs. An example of such reaction is a deprotection reaction of such compound by acid.

Typically, such compound to react the chemical species such as acid or base is a compound having a hetero atom, such as oxygen, sulfur, and nitrogen and a carbon atom bonded to the hetero atom or its derivative having a protecting group for a substituent containing the hetero atom. More typically, such compound has a protecting group for carbonyl group, alcohol or carboxylic acid.

Typical examples are represented by the following formula A or B (cyclic protecting group), where X is a hetero atom having electronegativity such as atom Groups 15 and 16, each of R¹, R², R³ and R⁴ is an alkyl or aryl group that may or may not contain at least one hetero atom and n is integer. It is preferred that: X is an oxygen atom or a sulfur atom; at least one of R¹ and R² is an aryl group; and n is from 1 or 5.

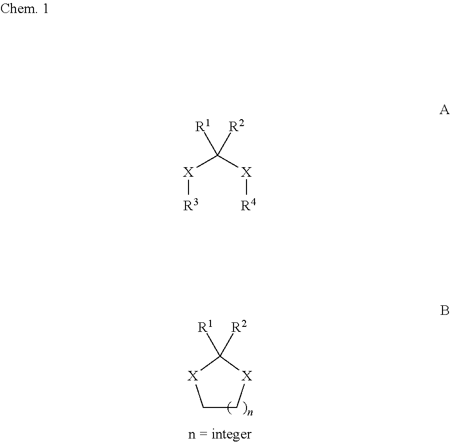

Such product enhances a reaction, such as generation of acid from the precursor, by donating an electron to the precursor or receiving an electron from the precursor triggered by feeding of energy to the composition.

It is preferred that such product has a pi-conjugated system containing at least one aromatic ring or at least one multiple bond. More typically, such product may have at least two aromatic rings and at least one multiple bond that is conjugated with at least one of the at least two aromatic rings.

Such product may have at least one electron-donating substituent such as alkoxy, alkylthio, arylthio, alkyl amino, and/or aryl amino on at least one aromatic ring. Examples of typical multiple bond(s) included in such product are carbon-oxygen double bond, carbon-carbon double bond, carbon-carbon triple bond, carbon-nitrogen double bond, carbon-nitrogen triple bond, and carbon-sulfur double bond.

More typically, such product is a diaryl ketone having at least one electron-donating group on the aromatic ring. Such product can act as a photosensitizer.

A devitalizing agent for deactivating such photosensitizer can be used for a purpose such as attainment of high resolution or low-line edge roughness (LER). A typical example of such devitalizing agent is a compound acting as a quencher of an excited state of such photosensitizer; more concretely, a compound acting as an electron-acceptor accepting an electron from such photosensitizer or an electron donor donating an electron to such photosensitizer. Such devitalizing agent can be added to any one of such compositions mentioned above.

It is preferred that the lowest singlet excited state of such product have a pi-pi* nature because such a singlet excited state has a relatively longer lifetime to transfer its electron to a precursor and has relatively low reactivity. A compound of this lowest triplet excited state has a pi-pi* nature that can be used as such product because the possibility of electron donation to the precursor or electron reception from the precursor can increase due to its longer lifetime compared to a singlet pi-pi* excited state. A compound of this lowest triplet excited state has an n-pi* nature that can be used as such product because such product can easily react with a precursor due to its high reactivity.

### BRIEF DESCRIPTION OF THE DRAWINGS

In the drawings, which illustrate what is currently considered to be the best mode for carrying out the invention:

FIG. 1 shows a typical reaction scheme of a composition related to an aspect of this disclosure; and

FIG. 2 shows fabrication processes of a device such as an integrated circuit (IC) using a photoresist related to an aspect of this disclosure.

### DETAILED DESCRIPTION

Experimental Procedures

Synthesis of 2-[1-(4-methoxy-phenyl)-ethoxy]tetrahydropyran (Compound 1).

2.75 grams of 2H-dihydropyran and 0.74 g of pyridinium p-toluenesulfonate are dissolved in 30.0 grams of methylene chloride. 2.0 g of 1-(4-methoxyphenyl)-ethanol dissolved by 8.0 grams of methylene chloride is added dropwise to the mixture containing 2H-dihydropyran and pyridinium p-toluenesulfonate over 30 minutes. After that, the mixture is stirred at 25 degrees Celsius for 3 hours. Afterward, the mixture is further stirred after addition of 3% aqueous solution of sodium carbonate and then extracted with 20.0 ethyl acetate. The organic phase is washed with water. Thereafter, ethyl acetate is distilled away, thereby obtaining 1.99 g of 2-[1-(4-methoxy-phenyl)-ethoxy]-tetrahydropyran.

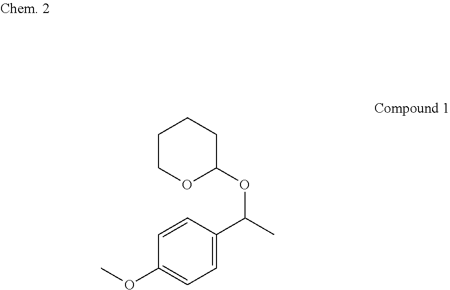 [SMILES: COc1ccc(C(C)OC2CCCCO2)cc1]

Synthesis of 2,2′,4,4′-tetramethoxybenzophenone.

2.00 g of 2,2′,4,4′-tetrahydroxybenzophenone, 3.68 g of dimethyl sulfate, and 4.03 g of potassium carbonate are dissolved in 12.0 g of acetone. The mixture is stirred at reflux temperature for 8 hours. Next, the mixture is cooled to 25 degrees Celsius and it is further stirred for 10 minutes after addition of 60.0 g of water and a deposit is filtrated. Then the deposit is dissolved in 20.0 g ethyl acetate and the organic phase is washed with water. Thereafter, ethyl acetate is distilled away, and the resultant is purified by recrystallization using 15.0 g of ethanol, thereby obtaining 1.40 g of 2,2′,4,4′-tetramethoxybenzophenone.

Synthesis of bis-(2,4-dimethoxyphenyl)-dimethoxymethane.

7.0 g of 2,2′,4,4′-tetramethoxybenzophenone, is dissolved in 27.8 g of thionyl chloride. The mixture is stirred at reflux temperature for 5 hours. Next, the thionyl chloride is distilled away and the resultant is dissolved in 15 g of toluene. Then, the prepared solution is added dropwise over 1 hour to 30.1 g of a methanol solution containing 5.0 g of sodium methoxide at 5 degrees Celsius. Once the addition was complete, the mixture is warmed up to 25 degrees Celsius while stirring for 2 hours. The mixture is then further stirred after an addition of 50 g of pure water. Next, the methanol is distilled away, and the resultant is extracted by 35 g of toluene and the organic phase is washed with water. Thereafter, toluene is distilled away, thereby obtaining 3.87 g of crude bis-(2,4-dimethoxyphenyl)-dimethoxymethane as an oil.

Synthesis of 2,2-bis-(2,4-dimethoxyphenyl)-1,3-dioxolane (Compound 2)

3.8 g of crude bis-(2,4-dimethoxyphenyl)-dimethoxymethane, 0.03 g of compher sulfonic acid and 2.03 g of ethyleneglycol are dissolved in 5.7 g of tetrahydrofuran. The mixture is stirred at 25 degrees Celsius for 72 hours. Next, the organic solvents are distilled away and the resultant is dissolved in 11 g of dichloromethane. Then, the mixture is further stirred after addition of 5% aqueous solution of sodium carbonate and the organic phase is washed with 5% aqueous solution of sodium carbonate and water. Thereafter, dichloromethane is distilled away, and the residue is purified by silica gel column chromatography (ethyl acetate: hexane: triethylamine=10:90:0.01), thereby obtaining 2.5 g of 2,2-bis-(2,4-dimethoxyphenyl)-1,3-dioxolane.

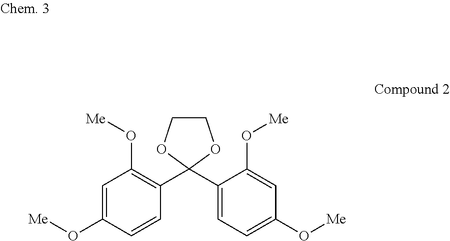 [SMILES: COc1ccc(C2(c3ccc(OC)cc3OC)OCCO2)c(OC)c1]

Synthesis of bis-(4-methoxy-phenyl)-dimethoxymethane (Compound 3).

2.0 grams of 4,4′-dimethoxy-benzophenone, 0.05 grams of bismuth (III) trifluoromethanesulfonate and 5.7 g of trimethyl orthofomate are dissolved in 5.0 g of methanol. The mixture is stirred at reflux temperature for 42 hours. Next, the mixture is cooled at 25 degrees Celsius and further stirred after addition of 5% aqueous NaHCO₃ solution. Then, the mixture is extracted with 30 grams ethyl acetate and the organic phase is washed with water. Thereafter, ethyl acetate is distilled away, and the resultant purified by silica gel column chromatography (ethyl acetate:hexane=1:9), thereby obtaining 1.71 grams of bis-(4-methoxy-phenyl)-dimethoxymethane.

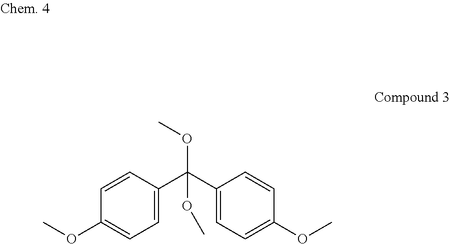

Synthesis of 2,4-dimethoxy-4′-(2-vinyloxy-ethoxy)-benzophenone

2.00 g of 2,4-dimethoxy-4′-hydroxybenzophenone, 2.48 g of 2-chloroethyl vinyl ether and 3.21 g of potassium carbonate are dissolved in 12.0 g of dimethyl formamide. The mixture is stirred at 110 degrees Celsius for 15 hours. Next, the mixture is cooled to 25 degrees Celsius, further stirred after addition of 60.0 g of water, then extracted with 24.0 g toluene, and the organic phase washed with water. Thereafter, toluene is distilled away, thereby obtaining 3.59 g of 2,4-dimethoxy-4′-(2-vinyloxy-ethoxy)-benzophenone.

Synthesis of 2,4-dimethoxy-4′-(2-hydroxy-ethoxy)-benzophenone

3.59 g of 2,4-dimethoxy-4′-(2-vinyloxy-ethoxy)-benzophenone, 0.28 g of pyridinium p-toluenesulfonate and 2.1 g of water are dissolved in 18.0 g of acetone. The mixture is stirred at 35 degrees Celsius for 12 hours. Next, the mixture is further stirred after addition of 3% aqueous solution of sodium carbonate, then extracted with 28.0 g ethyl acetate and the organic phase washed with water. Thereafter, ethyl acetate is distilled away, thereby obtaining 3.04 g of 2,4-dimethoxy-4′-(2-hydroxy-ethoxy)-benzophenone.

Synthesis of 2,4-dimethoxy-4′-(2-acetoxy-ethyl)-benzophenone.

3.0 g of 2,4-dimethoxy-4′-(2-hydroxy-ethoxy)-benzophenone and 1.1 g of acetic anhydride are dissolved in 21 g of tetrahydrofuran. 1.2 g of triethylamine dissolved in 3.6 g of tetrahydrofuran is added dropwise to the tetrahydrofuran solution containing 2,4-dimethoxy-4′-(2-hydroxy-ethoxy)-benzophenone over 10 minutes and then stirred at 25 degrees Celsius for 3 hours. Next, the mixture is further stirred after addition of water, then extracted with 30 g ethyl acetate and the organic phase washed with water. Thereafter, ethyl acetate is distilled away, and the residue is purified by silica gel column chromatography (ethyl acetate:hexane=1:9), thereby obtaining 2.72 g of 2,4-dimethoxy-4′-(2-acetoxy-ethyl)-benzophenone.

Synthesis of (2,4-dimethoxyphenyl)-[4′-(2-hydroxy-ethoxy)-phenyl]-dimethoxymethane

Synthesis of (2,4-dimethoxyphenyl)-[4′-(2-hydroxy-ethoxy)-phenyl]-dimethoxymethane as a target substance is synthesized and obtained according to the synthesis of bis-(2,4-dimethoxyphenyl)-dimethoxymethane mentioned above, except for using 2,4-dimethoxy-4′-(2-acetoxy-ethyl)-benzophenone instead of 2,2′,4,4′-tetramethoxybenzophenone for the synthesis of bis-(2,4-dimethoxyphenyl)-dimethoxymethane.

Synthesis of (2,4-dimethoxyphenyl)-[4′-(2-hydroxy-ethoxy)-phenyl]-1, 3 -dioxolane

Synthesis of (2,4-dimethoxyphenyl)-[4′-(2-hydroxy-ethoxy)-phenyl]-1, 3-dioxolane as a target substance is synthesized and obtained according to the synthesis of the Compound 2 mentioned above, except for using (2,4-dimethoxyphenyl)-[4′-(2-hydroxy-ethoxy)-phenyl]-dimethoxymethane instead of bis-(2,4-dimethoxyphenyl)-dimethoxymethane for the synthesis of Compound 2.

(2,4-dimethoxyphenye-[4′-(2-methacyloxy-ethoxy)-phenyl]-1,3-dioxolane (Compound 4).

Synthesis of (2,4-dimethoxyphenyl)-[4′-(2-methacyloxy-ethoxy)-phenyl]-1,3-dioxolane as a target substance is synthesized and obtained according to the synthesis of the 2,4-dimethoxy-4′-(2-acetloxy-ethyl)-benzophenone mentioned above, except for using methacrylic anhydride instead of acetic anhydride for the synthesis of 2,4-dimethoxy-4′-(2-acetloxy-ethyl)-benzophenone.

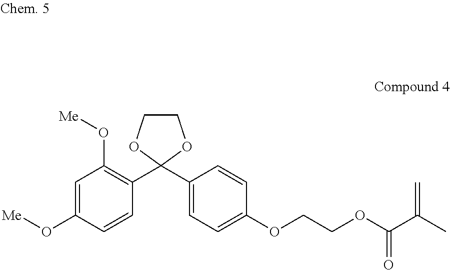 [SMILES: C=C(C)C(=O)OCCOc1ccc(C2(c3ccc(OC)cc3OC)OCCO2)cc1]

Synthesis of 1-[4-(2-vinyloxy-ethoxy)-phenyl]-ethanone

Synthesis of 1-[4-(2-vinyloxy-ethoxy)-phenyl]-ethanone as a target substance is synthesized and obtained according to the synthesis of the 2,4-dimethoxy-4′-(2-vinyloxy-ethoxy)-benzophenone mentioned above, except for using 4-hydroxy-acetophenone instead of 2,4-dimethoxy-4′-hydroxybenzophenone for the synthesis of 2,4-dimethoxy-4′-(2-vinyloxy-ethoxy)-benzophenone.

Synthesis of 1-[4-(2-hydroxy-ethoxy)-phenyl]-ethanone

Synthesis of 1-[4-(2-hydroxy-ethoxy)-phenyl]-ethanone as a target substance is synthesized and obtained according to the synthesis of the 2,4-dimethoxy-4′-(2-hydroxy-ethoxy)-benzophenone mentioned above, except for using 1-[4-(2-vinyloxy-ethoxy)-phenyl]-ethanone instead of 2,4-dimethoxy-4′-(2-vinyloxy-ethoxy)-benzophenone for the synthesis of 2,4-dimethoxy-4′-(2-hydroxy-ethoxy)-benzophenone.

Synthesis of 2-methyl-acrylic acid 2-(4-acetyl-phenoxy)-ethyl ester

Synthesis of 2-methyl-acrylic acid 2-(4-acetyl-phenoxy)-ethyl ester as a target substance is synthesized and obtained according to the synthesis of 2,4-dimethoxy-4′-(2-acetoxy-ethyl)-benzophenone mentioned above, except for using 1-[4-(2-hydroxy-ethoxy)-phenyl]-ethanone and methacrylic anhydride instead of 2,4-dimethoxy-4′-(2-hydroxy-ethoxy)-benzophenone and acetic anhydride, respectively, for synthesis of 2,4-dimethoxy-4′-(2-acetoxy-ethyl)-benzophenone.

Synthesis of 2-methyl-acrylic acid 2-[4-(1-hydroxy-ethyl)-phenoxy]-ethyl ester

3.0 g of 2-methyl-acrylic acid 2-(4-acetyl-phenoxy)-ethyl ester is dissolved in 24.0 g of tetrahydrofuran. 0.92 g of sodium boron hydride dissolved in water is added to the tetrahydrofuran solution. The mixture is stirred at 25 degrees Celsius for 2 hours. Next, the mixture is added to the 60 g of water, then extracted with 20.0 g ethyl acetate and the organic phase washed with water. Thereafter, ethyl acetate is distilled away, thereby obtaining 2.5 g of 2-methyl-acrylic acid 2-[4-(1-hydroxy-ethyl)-phenoxy]-ethyl ester.

Synthesis of 2-methyl-acrylic acid 2-{4-[1(tetrahydro-pyran-2-yloxy)-ethyl]-phenoxy}-ethyl ester (Compound 5).

Synthesis of 2-methyl-acrylic acid 2-{4-[1-(tetrahydro-pyran-2-yloxy)-ethyl]-phenoxy}-ethyl ester as a target substance is synthesized and obtained according to the synthesis of the Compound 1 above, except for using 2-methyl-acrylic acid 2-[4-(1-hydroxy-ethyl)-phenoxy]-ethyl ester instead of 1-(4-methoxyphenyl)-ethanol for the synthesis of Compound 1.

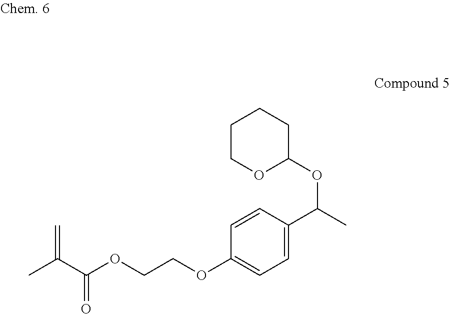 [SMILES: C=C(C)C(=O)OCCOc1ccc(C(C)OC2CCCCO2)cc1]

A solution containing 5.0 g of alpha-methacryloyloxy-gamma-butylolactone, 6.03 g of 2-methyladamantane-2-methacrylate, and 4.34 g of 3-hydroxyadamantane-1-methacrylate, 0.51 g of dimethyl-2,2′-azobis(2-methylpropionate), and 26.1 g of tetrahydrofuran is prepared. The prepared solution is added dropwise over 4 hours to 20.0 g of tetrahydrofuran placed in flask with stirring and boiling. After the addition of the prepared solution, the mixture is heated to reflux for 2 hours and cooled to room temperature. Addition of the mixture by drops to a mixed liquid containing 160 g of hexane and 18 g of tetrahydrofuran while vigorously stirring precipitates the copolymer. The copolymer is isolated by filtration. Purification of the copolymer is carried out by vacuum drying following two washings by 70 g of hexane, thereby obtaining 8.5 g of white powder of the copolymer.

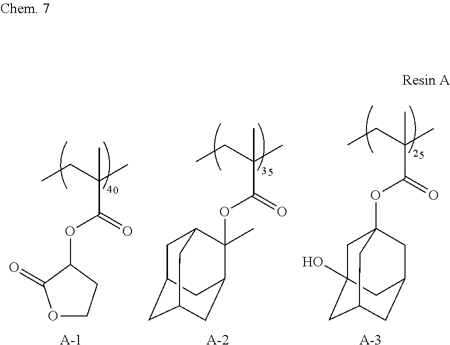

A solution containing 0.80 g of Compound 4, 3.8 g of alpha-methacryloyloxy-gamma-butylolactone, 2.9 g of 2-methyladamantane-2-methacrylate, 2.8 g of 3-hydroxyadamantane-1-methacrylate, 0.13 g of butyl mercaptane, 0.56 g of dimethyl-2,2′-azobis(2-methylpropionate) and 12.1 g of tetrahydrofuran is prepared. The prepared solution is added dropwise over 4 hours to 4.2 g of tetrahydrofuran placed in a flask while stirring and boiling under nitrogen atmosphere. After the addition of the prepared solution, the mixture is heated to reflux for 2 hours and cooled to room temperature. Addition of the mixture by drops to a mixed liquid containing 107 g of hexane and 11 g of tetrahydrofuran while vigorously stirring precipitates the copolymer. The copolymer is isolated by filtration. Purification of the copolymer is carried out by vacuum drying following two washings by 37 g of hexane, thereby obtaining 6.21 g of white powder of the copolymer (Resin B).

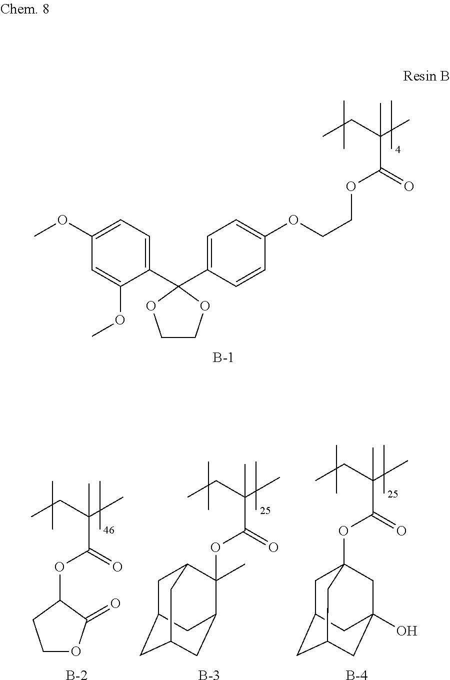

A solution containing 0.80 g of Compound 4, 0.65 g of Compound 5, 3.9 g of alpha-methacryloyloxy-gamma-butylolactone, 2.8 g of 2-methyladamantane-2-methacrylate, 2.3 g of 3-hydroxyadamantane-1-methacrylate, 0.12 g of butyl mercaptane, 0.53 g of dimethyl-2,2′-azobis(2-methylpropionate) and 12.2 g of tetrahydrofuran is prepared. The prepared solution is added dropwise for 4 hours to 8.6 g of tetrahydrofuran placed in a flask with stirring and boiling under nitrogen atmosphere. After the addition of the prepared solution, the mixture is heated to reflux for 2 hours and cooled to room temperature. Addition of the mixture by drops to a mixed liquid containing 108 g of hexane and 12 g of tetrahydrofuran while vigorously stirring precipitates the copolymer. The copolymer is isolated by filtration. Purification of the copolymer is carried out by vacuum drying following two washings by 37 g of hexane, thereby obtaining 6.0 g of white powder of the copolymer (Resin C).

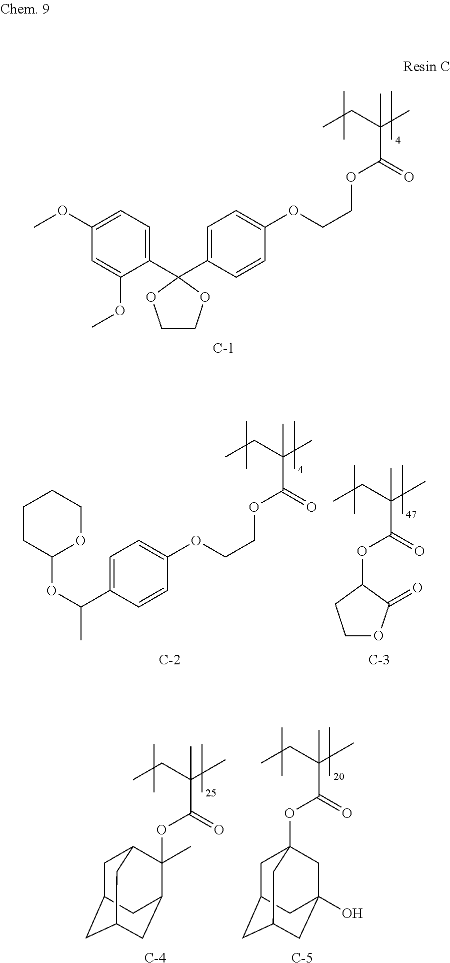

A solution containing 0.8 g of Compound 4, 0.64 g of Compound 5, 5.0 g of alpha-methacryloyloxy-gamma-butylolactone, 3.0 g of 2-methyladamantane-2-methacrylate, 3.8 g of 3-hydroxyadamantane-l-methacrylate, 0.64 g of 5-phenyl-dibenzothiophenium 1,1-difluoro-2-(2-methyl-acryloyloxy)-ethanesulfonate, 0.17 g of butyl mercaptane, 0.70 g of dimethyl-2,2′-azobis(2-methylpropionate) and 14.3 g of tetrahydrofuran is prepared. 5-phenyl-dibenzothiophenium 1,1-difluoro-2-(2-methyl-acryloyloxy)-ethanesulfonate functions as a PAG moiety. The prepared solution is added dropwise for 4 hours to 6.0 g of tetrahydrofuran placed in a flask while stirring and boiling. After the addition of the prepared solution, the mixture is heated to reflux for 2 hours and cooled to room temperature. Addition of the mixture by drops to a mixed liquid containing 126 g of hexane and 14 g of tetrahydrofuran while vigorously stirring precipitates the copolymer. The copolymer is isolated by filtration. Purification of the copolymer is carried out by vacuum drying following two washings by 44 g of hexane and two washings by methanol, thereby obtaining 6.4 g of white powder of the copolymer (Resin D).

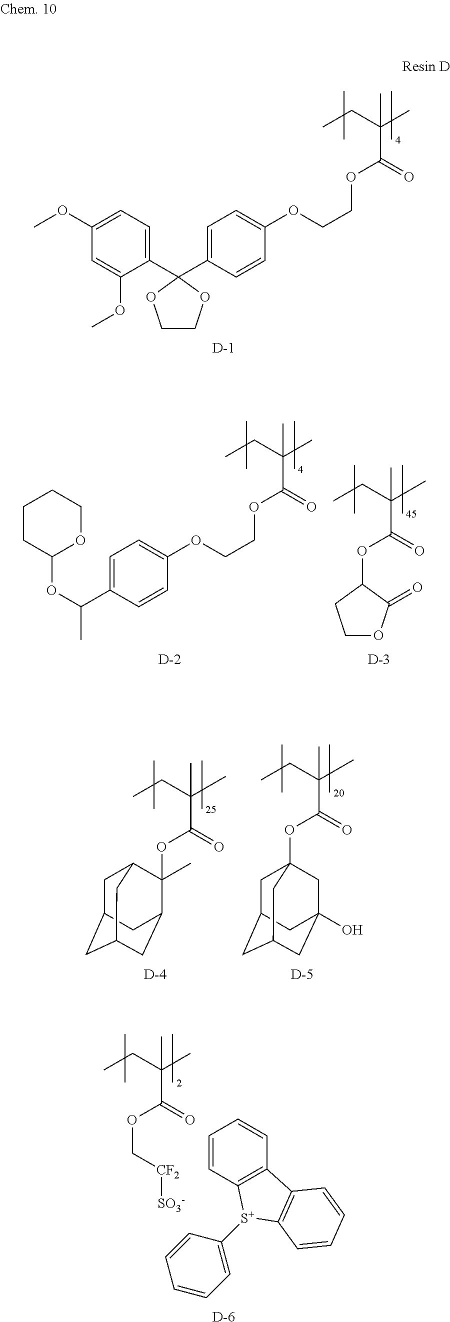

Preparation of Samples for Evaluation (the “Evaluation Samples”)

Evaluation Samples 1-13 are prepared by dissolving in 7000 mg of cyclohexanone (i) 0.043 mmol of a PAG selected from a group consisting of diphenyliodonium nonafluorobutanesulfonate (DPI-PFBS) and phenyl dibenzothionium nonafluorobutanesulfonate (PBpS-PFBS), (ii) a resin selected from a group consisting of 500 mg of Resins A, 489 mg of B, 507 mg of C, and 486 mg of D in order to precisely adjust the composition ratio of PAG and Compound for each sample, and (iii) at least 0.086 mmol of one additive selected from a group consisting of Compounds mentioned above, or (iv) 0 mmol of additive.

TABLE 1
Evaluation Samples for evaluation for efficiencies of patterning

| | Resin | PAG | Additive | | Solvent |
|---|---|---|---|---|---|
| Evaluation | Resin A | DPI- | — | | Cyclo- |
| Sample 1 | | PFBS | | | hexanone |
| Evaluation | | | Compound 1 | | |
| Sample 2 | | | | | |
| Evaluation | | | Compound 2 | | |
| Sample 3 | | | | | |
| Evaluation | | | Compound 1 | Compound 2 | |
| Sample 4 | | | | | |
| Evaluation | | PBpS- | — | | |
| Sample 5 | | PFBS | | | |
| Evaluation | | | Compound 1 | | |
| Sample 6 | | | | | |
| Evaluation | | | Compound 2 | | |
| Sample 7 | | | | | |
| Evaluation | | | Compound 1 | Compound 2 | |
| Sample 8 | | | | | |
| Evaluation | | | Compound 1 | Compound 3 | |
| Sample 9 | | | | | |

| | | | |
|---|---|---|---|
| Evaluation | Resin B | | — |
| Sample 10 | | | |
| Evaluation | | | Compound 1 |
| Sample 11 | | | |
| Evaluation | Resin C | | — |
| Sample 12 | | | |
| Evaluation | Resin D | — | — |
| Sample 13 | | | |

Evaluation of Sensitivity

Before applying the Evaluation Samples to Si wafers, hexamethyldisilazane (HMDS, Tokyo Chemical Industry) is spin-coated at 2000 rpm for 20 seconds on the surfaces of Si wafers and baked at 110 degrees Celsius for 1 minute. Then, the Evaluation Samples are spin-coated on the surfaces of the Si wafers, which have been treated with HMDS, at 4000 rpm for 20 seconds to form coated films. The prebake of the coated films is performed at 110 degrees Celsius for 60 seconds. Then, the coated films of the Evaluation Samples are exposed to 30 keV EB output from EB drawing system. Next, irradiations of the coated films with a UV light are carried out at an ambient condition. After the UV light exposure, a post-exposure-bake (PEB) is carried out at 100 degrees Celsius for 60 seconds. The coated films are developed with NMD-3 (tetra-methyl ammonium hydroxide 2.38%, Tokyo Ohka Kogyo) for 60 seconds at 25 degrees Celsius and rinsed with deionized water for 10 seconds. The thickness of the coating films measured using a film thickness measurement tool is approximately 150 nm. A sensitivity (E₀ sensitivity) is evaluated by measuring the dose size to form a pattern constituted by 2-micrometer lines where the thickness of the coating film is not zero and 2-micrometer spaces where the thickness of the coating film is zero using 30 keV EBL system JSM-6500F (JEOL, beam current: 12.5 pA, <1E-4 Pa) with Beam Draw (Tokyo Technology) and FL-6BL (bright line is mainly from 350 nm to 400 nm, Hitachi), and UV dose for E₀ sensitivity is calculated by means of a measurement of illuminance of UV source by 365 nm illuminometer (USHIO UIT-150, UVD-S365).

TABLE 2
The total doses for E₀ by electron beam
(EB) and UV exposure for the Evaluation

Total dose for E₀

| | EB dose [μC/cm²] | UV dose [mJ/cm²] |
|---|---|---|
| Evaluation Sample 1 | 22.5 | 0 |
| | 22.5 | 200 |
| Evaluation Sample 2 | 18.8 | 0 |
| | 18.8 | 200 |
| Evaluation Sample 3 | 23.8 | 0 |
| | 11.3 | 200 |
| Evaluation Sample 4 | 20.0 | 0 |
| | 8.8 | 200 |
| Evaluation Sample 5 | 26.3 | 0 |
| | 26.3 | 200 |
| Evaluation Sample 6 | 22.5 | 0 |
| | 22.5 | 200 |
| Evaluation Sample 7 | 27.5 | 0 |
| | 11.3 | 200 |
| Evaluation Sample 8 | 22.5 | 0 |
| | 10.0 | 200 |
| Evaluation Sample 9 | 22.5 | 0 |
| | 18.8 | 200 |
| Evaluation Sample 10 | 26.3 | 0 |
| | 15.0 | 200 |
| Evaluation Sample 11 | 21.3 | 0 |
| | 10.0 | 200 |
| Evaluation Sample 12 | 21.3 | 0 |
| | 11.3 | 200 |
| Evaluation Sample 13 | 20.0 | 0 |
| | 10.0 | 200 |

The dose sizes measured for Evaluation Samples 2, 4, 6, 8, 9, 11, 12 and 13 containing Compound 1, C-2 moiety of Resin C and D-2 of Resin D acting as acid generation enhancer (AGE) when UV irradiations are not carried out are smaller than corresponding Evaluation Samples containing no additives as control samples. In other words, E₀ sensitivities of Evaluation Samples 2, 4, 6, 8, 9, 11, 12 and 13 are higher than corresponding control samples.

Radicals are considered to be generated from Compound 1, C-2 moiety of Resin C and D-2 of Resin D by having a hydrogen atom bonded to a carbon atom bonded to an oxygen atom between a pyranyl ring and the carbon atom and an aromatic ring. Such radicals can have reducing characters and reduce PAG even in their ground states. Such kind of radicals can be alcoholic derivatives formed from Compound 1, C-2 moiety of Resin C and D-2 of Resin D.

These results concerning Evaluation Samples 2, 4, 6, 8, 9, 11, 12 and 13 indicate that acid generation efficiencies is improved by reduction of PAG by such radicals.

The dose sizes measured for Evaluation Samples 3, 4, 7, 8, 9, 10, 11, 12 and 13 containing Compound 2, B-1 moiety of Resin B, C-1 moiety of Resin C and D-1 of Resin D of which deprotected derivative act as photosensitizer when UV irradiations following EB exposures are carried out are strikingly smaller than corresponding Evaluation Samples containing no additives as control samples. In other words, E₀ sensitivities of Evaluation Samples 3, 4, 7, 8, 9, 10, 11, 12 and 13 are strikingly higher than corresponding control samples.

Such photosensitizers have at least two aromatic rings or two pi-electron systems interacting mutually more strongly than corresponding compounds and moieties.

The results indicate that generated photosensitizers that are formed from Compound 2, B-1 moiety of Resin B, C-1 moiety of Resin C and D-1 of Resin D by decomposing by generated acid from PAG resulting from an EB exposure reduce PAG by absorbing the UV lights, the wavelength of which is longer than 350 nm.

Compound 2 has a higher electron-donating ability than Compound 3, B-1 moiety of Resin B, C-1 moiety of Resin C and D-1 of Resin D because Compound 2 has more electron-donating substituents on the aromatic rings. The E₀ sensitivity for Evaluation Sample 8 containing Compounds 1 and 2 is higher than that for Evaluation Sample 9 containing Compounds 1 and 3. This is thought to be due to higher electron-donating ability of Compound 2 in comparison with Compound 3. In contrast, the E₀ sensitivities for Evaluation Samples containing Resins B, C and D when UV irradiations are carried out are high even when the E₀ sensitivities are compared to those of Evaluation Samples containing Compound 2. This implies that an incorporation B-1, C-1 and D-1 moiety included in Resins B, C and D acting as photosensitizers into polymer enables homogeneous dispersion of the photosensitizers, which improves sensitivity in order to enhance acid generation efficiencies.

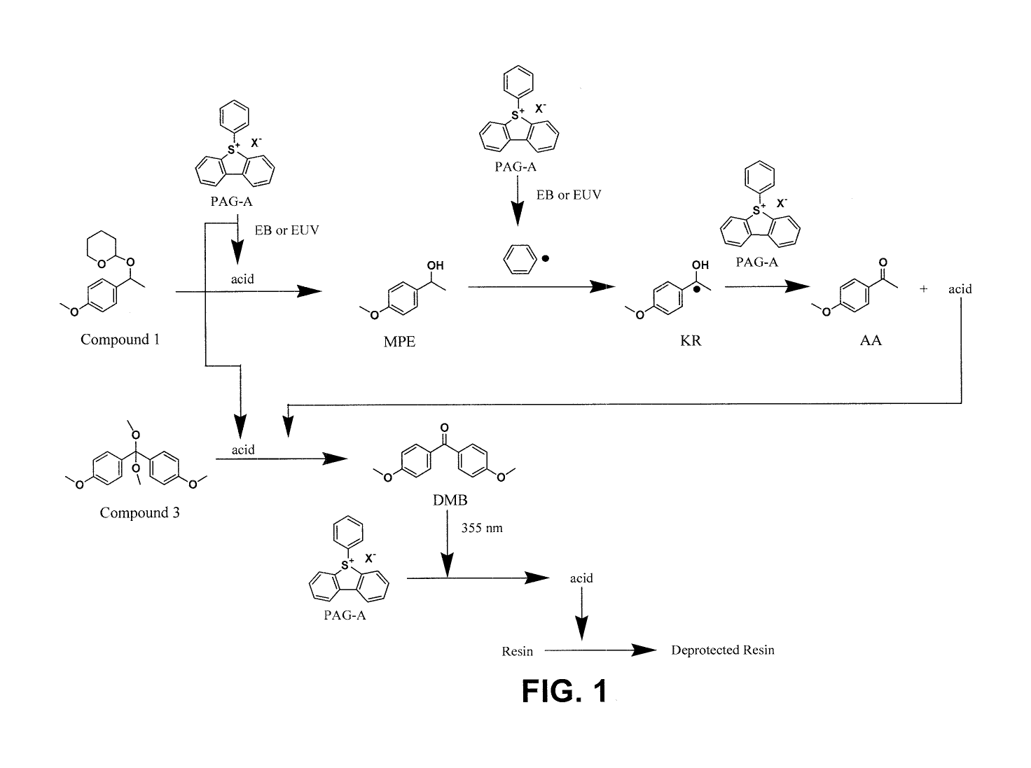

FIG. 1 shows a typical reaction scheme of a composition containing Compound 1 and Compound 3 that is related to an aspect of this disclosure and acts as a chemically amplified photoresist. An exposure of a photoacid generator (PAG-A) to electron beam (EB) or extreme ultraviolet (EUV) light yields acid, which reacts with Compound 1 to form a corresponding deprotected derivative (MPE). MPE has a hydrogen atom bonded to carbon atom bonded to the hydroxyl group by a radical such as phenyl radical to form a reactive intermediate such as ketyl radical (KR). KR is converted into a corresponding ketone (AA) by reducing PAG-A. The reduction of PAG-A by KR yields acid.

Compound 3 reacts with acid generated through the above process to form a corresponding ketone (DMB) in situ. DMB acts as a photosensitizer by absorbing a light such as an i-line light (365 nm).

In other words, the formation of the photosensitizer is enhanced by chemical species such as acid generated in the reaction triggered by an excitation of the composition. PAG-A receives an electron from the excited DMB to form acid.

Typically, such photosensitizer decays by reactions of such photosensitizer with another chemical species.

A quencher capable of quenching or neutralizing the acid can be added to such composition for a purpose such as attainment of high resolution, reduction of shot noise or low-line edge roughness (LER).

Since such photosensitizer is preferentially formed in a portion that has been exposed to a first light, such as EUV light, or first particle ray, such as EB, acid is preferentially formed in such exposed portion. Therefore, shot noise is suppressed.

Quencher in another portion other than such exposed portion neutralizes acid entering into such unexposed portion to improve LER and resolution.

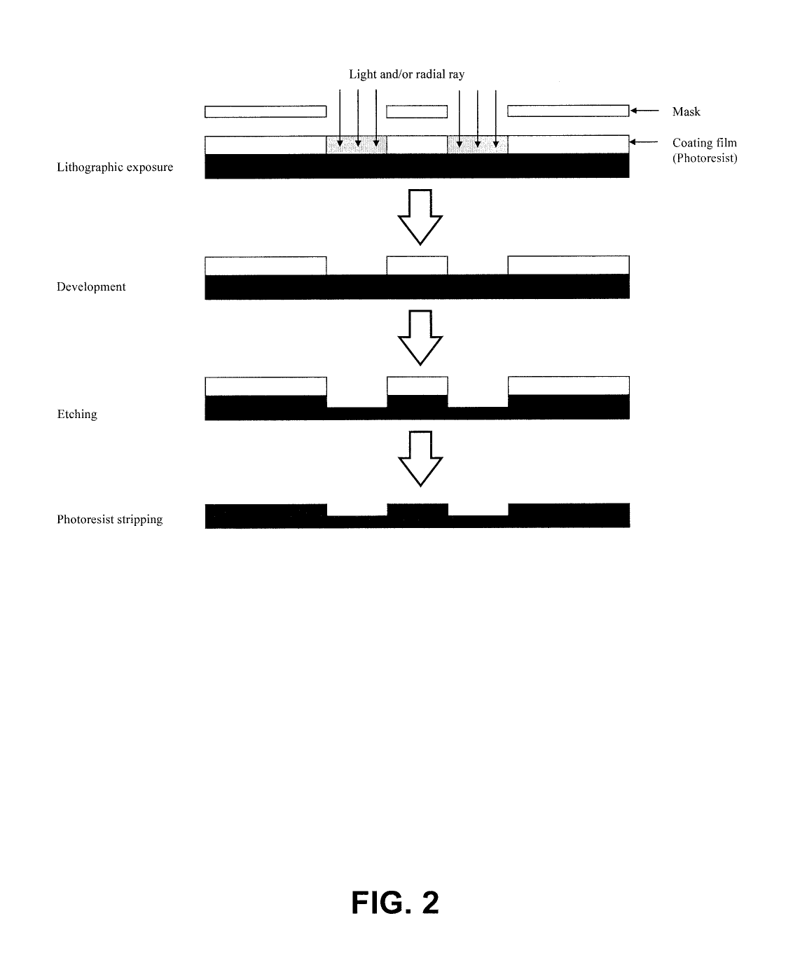

FIG. 2 shows fabrication processes of a device such as integrated circuit (IC) using a chemically amplified composition (CAR) photoresist including Compounds 1 and 3.

A silicon wafer is provided. The surface of the silicon wafer is oxidized by heating the silicon wafer in the presence of oxygen gas.

A solution of the CAR photoresist is applied to the surface of an Si wafer by spin coating to form a coating film. The coated film is prebaked.

An irradiation of the coating film with an EUV light through a mask is carried out after prebake of the Si wafer. The deprotection reaction of resin contained in the CAR photoresist is induced by acid generated by photoreaction of PAG and assistance by Compound 1 acting as an AGE and the photosensitizer generated in situ from Compound 2 by reacting with acid.

After the EUV irradiation of the coating film, an irradiation of the coating film with a light, the wavelength of which is equal to or longer than 300 nm is carried out without mask.

Development of the coating film that has been irradiated with the EUV light and the light, the wavelength of which is equal to or longer than 300 nm, is performed after the prebake.

The coating film and the silicon wafer are exposed to plasma. After that, the remaining film is removed.

An electronic device such as integrated circuit is fabricated utilizing the processes shown in FIG. 2. The deterioration of the device due to the irradiation with a light is suppressed compared to existing photoresists since times for irradiation of the coating film is shortened.

1-13. (canceled)

14. A composition, comprising:
a first reagent that generates a first chemical species; and
a precursor, which is a photoacid generator that that forms a second chemical species,
wherein:
at least one of a donation of an electron from the first chemical species and an acceptance of an electron by the first chemical species is able to occur;
the first chemical species converts to a first product by the at least one of the donation of the electron and the acceptance of the electron; and
the first reagent is an alcohol compound having a hydroxl group at least one aryl group connected to a carbon atom bonded to the hydroxyl group, and a hydrogen atom connected to the carbon atom, or an alcohol derivative thereof having a protecting group for the hydroxyl group.

15. The composition of claim 14, further comprising:
a second reagent represented by Formula (A) or Formula (B), wherein the second reagent generates a second product and
the at least one of a donation of an electron and an acceptance of an electron of the second product is able to occur by an excitation of the second product 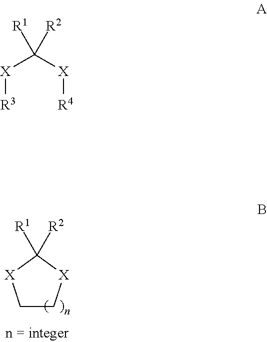
wherein:
each of R¹, R² R³ and R⁴ independently is an alkl or an aryl group that may or may not contain at least one hetero atom;
at least one of R¹ and R² is the aryl group;
X is an oxygen atom or a sulfur atom; and
n is an integer from 1 to 5.

16. The composition of claim 14, further comprising:
a compound having a dissociable group that is to react with the second chemical species.

17. (canceled)

18. The composition of claim 14, wherein the first chemical species is a ketyl radical formed by having a hydrogen atom of the first reagent abstracted.

19-23. (canceled)

24. A method for fabricating a device, the method comprising:
placing a composition on a member such that a film including the composition is disposed on the member;
generating the first product in the film by an exposure of the film to at least one of an electron beam and a first light, the wavelength of which is a first wavelength shorter than 50 nm; and
exposing the film to a second light, the wavelength of which is a second wavelength,
wherein the composition comprises:
a first reagent that generates a first chemical species and
a precursor, which is a photoacid generator that is able to form a second chemical species;
at least one of a donation of an electron from the first chemical species and an acceptance of an electron by the first chemical species is capable of occurring;
the first chemical species is to be converted to a first product by the at least one of the donation of the electron and the acceptance of the electron; and
the first reagent is an alcohol compound having a hydroxyl group, at least one aryl group connected to a carbon atom bonded to the hydroxyl group, and a hydrogen atom connected to the carbon atom or an alcohol derivative thereof having a protecting group for the hydroxyl group.

25. (canceled)

26. The method of claim 24, wherein the second wavelength is longer than 250 nm.

27. The method: of claim 24, wherein the at least one of the electron beam and the first light is carried out while a second portion of the coating film is not expensed to the at least one of the electron beam and the first light.

28. (canceled)

29. The method of claim 27, further comprising:
removing the first portion.

30. The composition of claim 14, wherein at least one of the aryl group has at least one electron-donating substituent.

31. The composition of claim 14, wherein the first product comprises:
a first group, which is an aryl group; and
a second group having a pi-electron system with a carbon-oxygen double bond.

32. The composition of claim 15, wherein both R¹ and R² are aryl groups.

33. The composition of claim 32, wherein the second product is a diaryl ketone having at least one electron-donating substituent on the aryl group.

34. The method according to claim 24, wherein the composition further comprises a second reagent is represented by Formula (A) or Formula (B), which second reagent is to generate a second product; and
the at least one of a donation of an electron and an acceptance of an electron of the second product is capable of occurring by an excitation of the second product 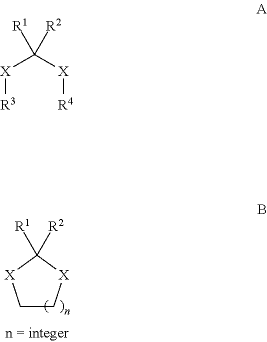
wherein:
each of R¹, R², R³ and R⁴ independently is an alkyl or an aryl group that may or may not contain at least one hetero atom;
at least one of R¹ and R² is the aryl group;
X is an oxygen atom or a sulfur atom; and
n is integer from 1 to 5.

35. The method according to claim 24, further comprising:
a compound having a dissociable group that is to react with the second chemical species.

36. The method according to claim 24, wherein the first chemical species is a ketyl radical formed by having a hydrogen atom of the first reagent abstracted.

37. The method according to claim 34, wherein both R¹ and R² are aryl groups.
